(19) United States
(12) Patent Application Publication
(10) Pub. No.: US 2025/0252986 A1
(43) Pub. Date: Aug. 7, 2025

(54) CONTROLLER, MEMORY DEVICE, AND STORAGE DEVICE

(71) Applicant: SK hynix Inc., Icheon-si (KR)

(72) Inventor: Dong Sop LEE, Icheon-si (KR)

(21) Appl. No.: 19/014,901

(22) Filed: Jan. 9, 2025

(30) Foreign Application Priority Data
Feb. 2, 2024 (KR) 10-2024-0016308

(51) Int. Cl. G11C 8/06; G11C 8/10; G11C 8/18

(52) U.S. Cl. CPC G11C 8/06; G11C 8/10; G11C 8/18

(57) ABSTRACT

A portion of an address bit for column addressing or an address bit for row addressing for a memory is used for addressing. Addressing may be performed using another address bit, thereby making it possible to easily address various types of memories or extended memories without changing or extending the address bit.

### CROSS-REFERENCE TO RELATED APPLICATION

The present application claims priority under 35 U.S.C. § 119(a) to Korean patent application number 10-2024-0016308 filed on Feb. 2, 2024, which is incorporated herein by reference in its entirety.

### TECHNICAL FIELD

Embodiments of the present disclosure relate to a controller, a memory device, and a storage device.

### BACKGROUND

A storage device may include a memory including a plurality of memory cells that store data. The storage device may include a controller that controls the operation of the memory.

The controller may control an operation of the memory according to a command received from an external device, for example. The controller may control an operation of writing data to a specific area of the memory or reading data written to the corresponding area according to a command.

The design of the memory may be changed to enhance the performance of the memory. In this case, redesign of the controller may be required by the design change in the memory.

### SUMMARY

Embodiments of the present disclosure may provide a memory that may be controlled by the same controller even when the type or design of memory included in the storage device is changed.

Embodiments of the present disclosure may provide a storage device comprising a memory including a memory cell array including a plurality of word lines and a plurality of bit lines, a first decoder selecting an operation word line from among the plurality of word lines, and a second decoder selecting an operation bit line from among the plurality of bit lines and a controller transmitting a first address bit and a second address bit, a first portion of the first address bit indicating the operation word line for selection, and a second portion of the first address bit and the second address bit indicating the operation bit line for selection.

Embodiments of the present disclosure may provide a memory device comprising a plurality of first driving lines arranged in a first direction, a plurality of second driving lines arranged in a second direction crossing the first direction, a first decoder selecting a first driving line operating from among the plurality of first driving lines based on a first portion of a first address bit, and a second decoder selecting a second driving line operating from among the plurality of second driving lines based on a second portion of the first address bit and a second address bit.

Embodiments of the present disclosure may provide a controller comprising an address bit generator generating a first bit indicating an operation word line among a plurality of word lines, a second bit indicating one among a plurality of sub pages, and a third bit indicating an operation bit line among a plurality of bit lines included in a sub page indicated by the second bit and an address bit transmitter transmitting the first bit and the second bit in a first period and transmitting the third bit in a second period.

According to embodiments of the present disclosure, the operation of a design changed memory may be controlled without changing the design of the controller, thereby facilitating optimization and extension of the memory.

### BRIEF DESCRIPTION OF THE DRAWINGS

FIG. 1 is a view illustrating a schematic configuration of a storage device according to embodiments of the present disclosure.

FIG. 2 is a view illustrating a schematic configuration of a memory according to embodiments of the present disclosure.

FIG. 3 is a view illustrating an operating method of a memory according to embodiments of the present disclosure.

FIGS. 4 and 5 are views illustrating other operating methods of a memory according to embodiments of the present disclosure.

FIG. 6 is a view illustrating a method of performing addressing by a memory according to embodiments of the present disclosure.

FIG. 7 is a view illustrating an example of an address bit received by a memory according to embodiments of the present disclosure.

FIG. 8 is a view illustrating an example of timing at which a memory receives an address bit according to embodiments of the present disclosure.

FIG. 9 is a view illustrating a configuration of a controller according to embodiments of the present disclosure.

### DETAIL DESCRIPTION OF THE EXEMPLARY EMBODIMENTS

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings. Further, in the following description of examples or embodiments of the present disclosure, detailed descriptions of well-known functions and components incorporated herein will be omitted when it is determined that the description may make the subject matter in some embodiments of the present disclosure more unclear. The terms such as “including”, “having”, “containing”, “constituting” “made up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, or manufacturing methods, these terms may be used to describe non-consecutive or non-sequential processes or operations unless the term “directly” or “immediately” is used together.

In addition, when any dimensions, relative sizes etc. are mentioned, it should be considered that numerical values for elements or features, or corresponding information (e.g., level, range, etc.) include a tolerance or error margin that may be caused by various factors (e.g., process factors, internal or external impact, noise, etc.) even when a relevant description is not specified. Further, the term “may” fully encompasses all the meanings of the term “can”.

Hereinafter, various embodiments of the present disclosure will be described in detail with reference to accompanying drawings.

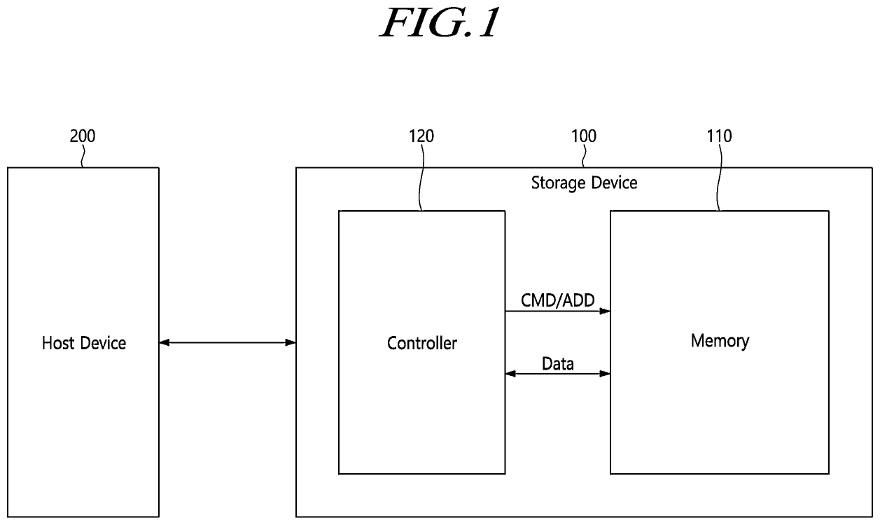

FIG. 1 is a view illustrating a schematic configuration of a storage device according to embodiments of the present disclosure.

Referring to FIG. 1, a storage device 100 may include at least one memory 110. The storage device 100 may include a controller 120 that controls the operation of the memory 110.

The memory 110 may be, e.g., a volatile memory such as DRAM, SDRAM, DDR SDRAM, and LPDDR SDRAM, but embodiments of the present disclosure are not limited thereto. For example, the memory 110 may be a nonvolatile memory such as a NAND flash memory, a three-dimensional (3D) NAND flash memory, or a NOR flash memory.

Further, the memory 110 may be one of various types of memories such as resistive RAM, phase change memory, magnetoresistive memory, ferroelectric memory, or spin injection magnetization inversion memory. Also, the memory 110 may be a processing-in-memory including an arithmetic function or a data processing function, in some embodiments of the present disclosure. In the present disclosure, the memory 110 may be referred to as a memory device.

The memory 110 may include a plurality of storage blocks. Each of the plurality of storage blocks may include a plurality of memory cells. The plurality of storage blocks may be divided into a plurality of banks, which are units controlled by the controller 120.

The controller 120 may control the operation of the memory 110 based on a command received from the outside. The controller 120 may also control the operation of the memory 110 based on its own command.

The controller 120 may transmit a command or address for controlling the operation of the memory 110 to the memory 110. The controller 120 may control, for example, an operation of writing data to the memory 110. The controller 120 may control an operation of reading data written to the memory 110. Data may be transmitted and received between the controller 120 and the memory 110.

The controller 120 may control a refresh operation or an erase operation on data written to the memory 110 according to the type of the memory 110.

The controller 120 may control the operation of the memory 110 based on a command received from an external host device 200.

The host device 200 may be, for example, a computer, an ultra mobile PC (UMPC), a workstation, a personal digital assistant (PDA), a tablet, a mobile phone, a smartphone, an e-book, a portable multimedia player (PMP), a portable game console, a navigation device, a black box, a digital camera, a digital camera, a digital multimedia broadcasting (DMB) player, a smart television, a digital voice recorder, a digital voice player, a digital video recorder, a digital video player, storage constituting a data center, one of various electronic devices constituting a telematics network, a radio frequency identification (RFID) device, and a moving device (e.g., a vehicle, robot, or drone) capable of driving under human control or autonomous driving. Alternatively, the host device 200 may be a virtual/augmented reality device that provides two-dimensional (2D) or three-dimensional (3D) virtual reality images or augmented reality images. The host device 200 may be any one of various electronic devices that require the storage device 100 capable of storing data.

The host device 200 may include at least one operating system. The operating system may generally manage and control the functions and operations of the host device 200, and may control mutual operations between the host device 200 and the storage device 100. The operating system may be divided into a general operating system and a mobile operating system according to the mobility of host device 200.

The controller 120 and the host device 200 may be devices separated from each other. In some embodiments of the present disclosure, the controller 120 and the host device 200 may be integrated into a single device. Hereinafter, for convenience of description, an example is described in which the controller 120 and the host device 200 are separated from each other.

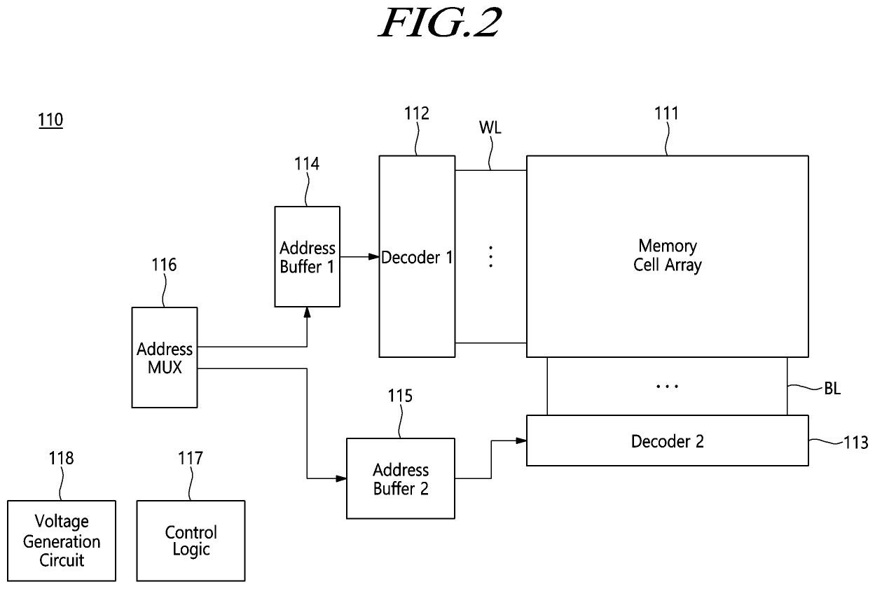

FIG. 2 is a view illustrating a schematic configuration of the memory 110 according to embodiments of the present disclosure.

Referring to FIG. 2, a memory 110 may include a memory cell array 111 including a plurality of memory cells. The memory cell array 111 may include a plurality of word lines WL disposed in a first direction. The memory cell array 111 may include a plurality of bit lines BL disposed in a second direction crossing the first direction.

The word line WL may drive a memory cell disposed in a row that is a target of a write operation or a read operation among the plurality of memory cells. Among the plurality of word lines WL, the word line that is the target for the operation may be referred to as an operation word line.

The bit line BL may control an operation of a memory cell disposed in a column that is a target of a write operation or a read operation among the plurality of memory cells. Among the plurality of bit lines BL, a bit line BL that is the target for the operation may be referred to as an operation bit line.

In the present disclosure, one of the word line WL and the bit line BL may be referred to as a first driving line, and the other may be referred to as a second driving line. For example, the word line WL may be referred to as a first driving line, and the bit line BL may be referred to as a second driving line. As another example, the bit line BL may be referred to as a first driving line, and the word line WL may be referred to as a second driving line.

The memory 110 may include at least one decoder for addressing the memory cell array 111.

For example, the memory 110 may include a first decoder 112 and a second decoder 113. In some embodiments of the present disclosure, the first decoder 112 and the second decoder 113 may be implemented in a single form and included in the memory 110.

The first decoder 112 may be, e.g., referred to as a row address decoder. The second decoder 113 may be, e.g., a column address decoder.

The first decoder 112 and the second decoder 113 may receive address bits.

The address bit may mean a bit indicating an address that is a target of a write operation or a read operation. A memory cell, which is a target for a write operation or a read operation, and a word line WL and a bit line BL driving the corresponding memory cell may be selected based on the address bit.

The first decoder 112 may select an operation word line, which is the target for the operation, from among the plurality of word lines WL based on the address bit. The second decoder 113 may select an operation bit line, which is the target for the operation, from among the plurality of bit lines BL based on the address bit.

The first decoder 112 and the second decoder 113 may select an operation word line and an operation bit line, respectively, by converting the address bit, and in some embodiments of the present disclosure, a single decoder may select an operation word line and an operation bit line.

Although not shown in FIG. 2, a read and write circuit may be disposed between the second decoder 113 and the bit line BL. The read and write circuit may include a page buffer in which data is stored during the write operation or the read operation. A write operation or a read operation, according to driving of the operation bit line selected by the second decoder 113, may be controlled by the read and write circuit.

The memory 110 may include at least one address buffer for storing an address bit received from the outside. For example, the memory 110 may include a first address buffer 114 and a second address buffer 115.

The first address buffer 114 may be referred to as a row address buffer. The second address buffer 115 may be referred to as a column address buffer.

In some embodiments of the present disclosure, the first address buffer 114 and the second address buffer 115 may be provided in an integrated form. Further, only a portion of the first address buffer 114 and the second address buffer 115 may be provided.

The first address buffer 114 may provide an address bit received from the outside to the first decoder 112. In some embodiments of the present disclosure, the first address buffer 114 and the first decoder 112 may be implemented in a single form.

The second address buffer 115 may provide an address bit received from the outside to the second decoder 113. In some embodiments of the present disclosure, the second address buffer 115 and the second decoder 113 may be implemented in a single form.

The memory 110 may include an address multiplexer 116 that discerns the type of address bit and transmits it to the address buffer.

The address multiplexer 116 may provide the address bit to the first address buffer 114 or the second address buffer 115 according to the type of the address bit. In some embodiments of the present disclosure, the address multiplexer 116 may directly provide the address bit to the first decoder 112 or the second decoder 113.

The memory 110 may include a control logic 117 that controls operations of the memory cell array 111, the first decoder 112, and the second decoder 113. The memory 110 may include a voltage generation circuit 118 that provides a voltage required for the operation of the memory cell array 111, the first decoder 112, the second decoder 113, or the like.

The memory 110 may select a memory cell, which is the target for the operation, by performing addressing based on an address bit received from the outside. Further, the memory 110 may select a word line WL and a bit line BL, which are the targets for the operation in the memory cell array 111, using some or a combination of the plurality of address bits.

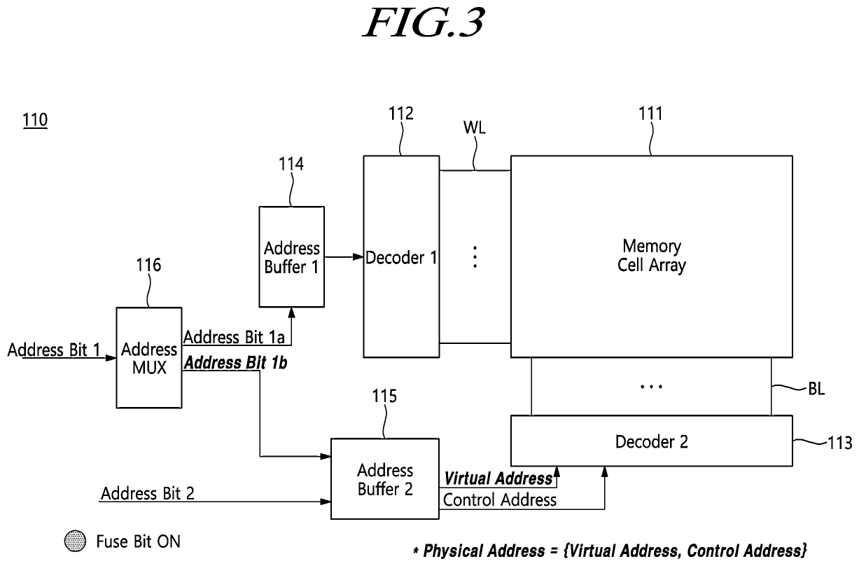

FIG. 3 is a view illustrating an operating method of a memory according to embodiments of the present disclosure.

Referring to FIG. 3, a memory 110 may receive a first address bit and a second address bit. The memory 110 may select an operation word line from among a plurality of word lines WL using at least a portion of the first address bit. The memory 110 may select an operation bit line from among a plurality of bit lines BL using at least a portion of the second address bit.

The memory 110 may select the operation bit line among the plurality of bit lines BL using at least a portion of the first address bit. In some embodiments of the present disclosure, the memory 110 may select an operation word line from among a plurality of word lines WL using at least a portion of the second address bit.

The memory 110 may select an operation word line or an operation bit line using a combination of the first address bit and the second address bit.

The memory 110 may operate in a first mode and a second mode according to an addressing method based on the address bit. The memory 110 may have a fuse bit for distinguishing the first mode and the second mode.

The fuse bit may be set, for example, to a first value in the first mode. The fuse bit may be set to a second value in the second mode. In the first mode, the fuse bit may be set to an on state, and in the second mode, the fuse bit may be set to an off state.

The memory 110 may perform addressing on the operation word line or the operation bit line using a combination of address bits in the first mode, in which the fuse bit is set to the first value.

For example, the address multiplexer 116 may receive the first address bit.

The address multiplexer 116 may latch a first portion (Address bit 1a) of the first address bit to the first address buffer 114. The address multiplexer 116 may latch the second portion (Address bit 1b) of the first address bit to the second address buffer 115. For example, the size of the first portion (Address bit 1a) of the first address bit may be larger than the size of the second portion (Address bit 1b) of the first address bit.

The first portion (Address bit 1a) of the first address bit may be latched to the first address buffer 114. The first decoder 112 may select the operation word line among the plurality of word lines WL of the memory cell array 111 using the first portion (Address bit 1a) of the first address bit latched to the first address buffer 114.

The second portion (Address bit 1b) of the first address bit may be latched to the second address buffer 115. The second address buffer 115 may receive a second address bit from outside of the second address buffer 115. The memory 110 may receive the first address bit and the second address bit from the controller 120 separately. Thus, the first address bit may be provided to the first address buffer 114. And the second address bit may be directly provided to the second address buffer 115.

The second decoder 113 may select the operation bit line among the plurality of bit lines BL of the memory cell array 111 using the second portion (Address bit 1b) of the first address bit latched to the second address buffer 115 and using the second address bit.

For example, the second decoder 113 may generate a virtual address based on the second portion (Address bit 1b) of the first address bit. Alternatively, the second decoder 113 may convert the second portion (Address bit 1b) of the first address bit into a virtual address. The virtual address may indicate, for example, one of bit line groups including two or more bit lines BL. Alternatively, the virtual address may indicate one of two or more sub pages included in the memory cell array 111.

The second decoder 113 may receive a control address based on the second address bit from the second address buffer 115. Alternatively, the second decoder 113 may receive the second address bit and convert the second address bit into a control address.

The second decoder 113 may select a bit line group or a sub page based on the virtual address. The second decoder 113 may select the operation bit line from among the bit lines BL included in the bit line group or the sub page based on the control address.

A physical address may be provided based on the virtual address and the control address.

Since the second decoder 113 selects the operation bit line using the second portion (Address bit 1b) of the first address bit, the size of the second address bit used for selecting the operation bit line may be smaller than the number of bit lines BL selectable in the memory cell array 111.

For example, the size of the second address bit may be 10 bits. The size of the second portion (Address bit 1b) of the first address bit may be 1 bit. The second address bit may indicate 1024 bit lines BL. Since the second portion (Address bit 1b) of the first address bit is used for addressing the operation bit line, the number of bit lines BL included in the memory cell array 111 may be 2048, which is more than 1024 lines that can be indicated by the second address bit.

If the size of the second portion (Address bit 1b) of the first address bit increases to 2 bits or more, addressing for a larger number of bit lines BL may be possible. According to embodiments of the present disclosure, addressing may be performed on the memory cell array 111 in which the number of bit lines BL is increased without changing a second address bit with a fixed size.

The second portion (Address bit 1b) of the first address bit may be a portion that is not used when addressing using the first address bit. In order to select the operation word line using the first address bit, only the first portion (Address bit 1a) of the first address bit may be used.

Since the addressing of the column is performed using the second portion (Address bit 1b) of the first address bit, which is not used when addressing the row of the memory cell array 111, the addressing of the memory cell array 111 may be performed without changing the second address bit used when addressing the column of the memory cell array 111.

Further, in some embodiments of the present disclosure, the operation word line may be selected using a portion of the second address bit (not illustrated herein). The operation word line may be selected using a portion of the second address bit and the first address bit. The operation bit line may be selected using the rest of the second address bit. When the number of the word lines increases and a portion of the second address bit is not used for addressing (selecting) the operation bit line, the portion of the second address bit may be used for addressing (selecting) the operation word line.

A portion of the second address bit for selecting the operation bit line and the first address bit for selecting the operation word line may be used for other addressing, so that addressing may be performed on various memory cell arrays 111 without changing the first address bit or the second address bit.

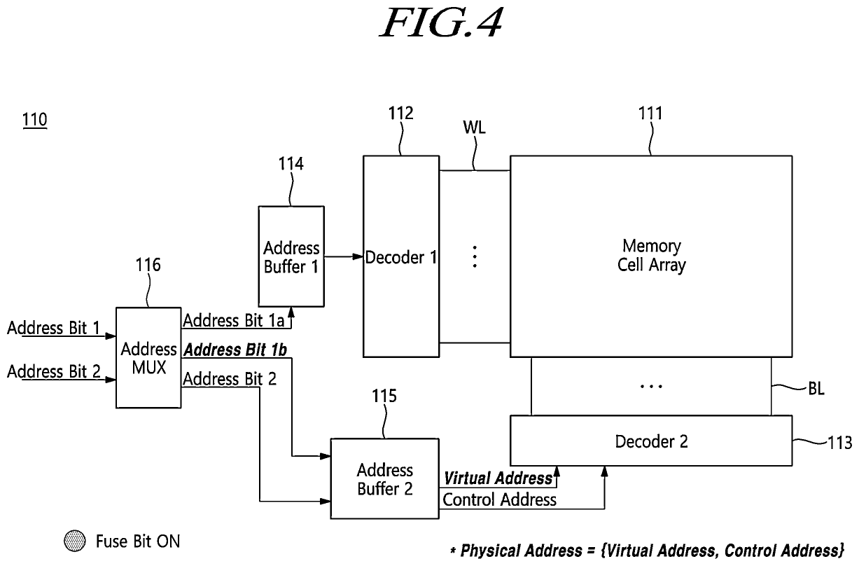

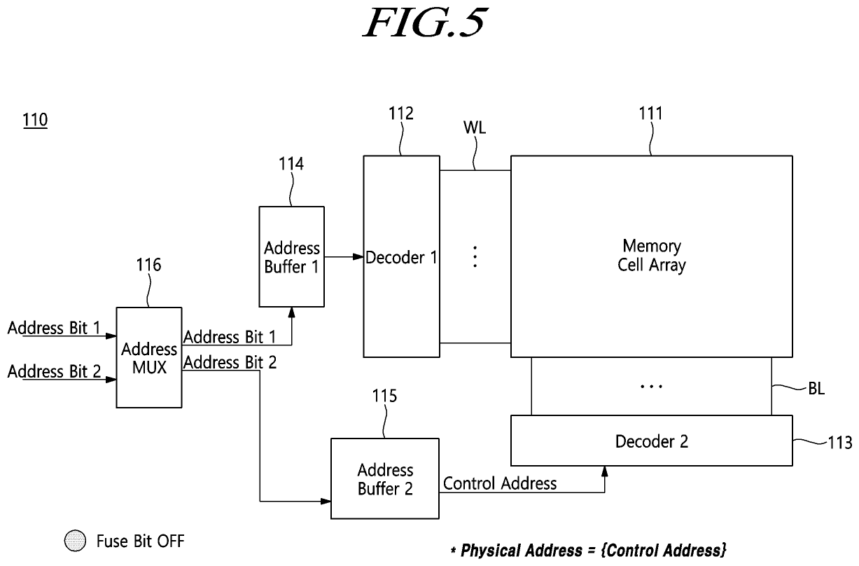

FIGS. 4 and 5 are views illustrating other operating methods of a memory according to embodiments of the present disclosure.

Referring to FIGS. 4 and 5, a memory 110 may include a memory cell array 111, a first decoder 112, a second decoder 113, a first address buffer 114, a second address buffer 115, and an address multiplexer 116. The memory 110 may have a fuse bit for setting to a first mode or a second mode.

For example, referring to FIG. 4, a memory 110 may operate in the first mode if the fuse bit is set to a first value. The memory 110 may perform addressing for selecting an operation word line or an operation bit line using at least a portion of the first address bit or the second address bit during a period of operating in the first mode.

For example, the address multiplexer 116 may receive the first address bit and the second address bit.

The address multiplexer 116 may discern the first address bit and the second address bit from each other and latch them to the first address buffer 114 and the second address buffer 115.

For example, the address multiplexer 116 may latch the first portion (Address bit 1a) of the first address bit to the first address buffer 114. The address multiplexer 116 may latch the second portion (Address bit 1b) of the first address bit to the second address buffer 115. The address multiplexer 116 may latch the second address bit to the second address buffer 115.

Since the address multiplexer 116 receives both the first address bit and the second address bit and latches them to the first address buffer 114 and the second address buffer 115, the memory 110 may latch a portion of the first address bit or a portion of the second address bit.

In some cases, when the a portion of the second address bit is used for selecting the operation word line with the first address bit, the address multiplexer 116 may latch the portion of the second address bit, the rest of the second address bit, and the first address bit to the first address buffer 114 and the second address buffer 115, respectively.

The first address buffer 114 may provide the first portion (Address bit 1a) of the first address bit to the first decoder 112. The first decoder 112 may perform addressing while selecting the operation word line from among the plurality of word lines WL based on the first portion (Address bit 1a) of the first address bit.

The second address buffer 115 may provide the second portion (Address bit 1b) of the first address bit and the second address bit to the second decoder 113. The second decoder 113 may perform addressing while selecting the operation bit line from among the plurality of bit lines BL based on the second portion (Address bit 1b) of the first address bit and the second address bit.

For example, the second decoder 113 may select a bit line group or sub page using a virtual address generated based on the second portion (Address bit 1b) of the first address bit. The second decoder 113 may select the operation bit line from among the bit lines BL included in the bit line group or the sub page based on the second address bit.

Even when the number of bit lines BLs addressed in the memory cell array 111 is larger than the number of selectable bit lines BLs based on the size of the second address bits, the addressing of the operation bit line may be performed using a portion of the first address bits.

Addressing may be possible without modifying the size of the first address bit or the second address bit according to the type or size of the memory 110.

Further, when addressing using the second address bit is possible, addressing of the operation bit line may be performed without using a portion of the first address bit.

For example, FIG. 5 illustrates an operation in which the fuse bit is set to the second value. The fuse bit may be set to an off state. The memory 110 may operate in the second mode according to the set value of the fuse bit.

The address multiplexer 116 of the memory 110 may receive the first address bit and the second address bit.

The address multiplexer 116 may latch the first address bit to the first address buffer 114. The address multiplexer 116 may latch the second address bit to the second address buffer 115.

The address multiplexer 116 may latch both the first portion (Address bit 1a) and the second portion (Address bit 1b) of the first address bit to the first address buffer 114. Alternatively, the address multiplexer 116 may latch only the first portion (Address bit 1a) of the first address bit to the first address buffer 114. The second portion (Address bit 1b) of the first address bit may not be received from the external source or may be latched internally, or may not be used for addressing.

The first decoder 112 may select the operation word line from among the plurality of word lines WL of the memory cell array 111 using the first address bit latched to the first address buffer 114.

The second decoder 113 may select the operation bit line among the plurality of bit lines BL of the memory cell array 111 using the second address bit latched to the second address buffer 115. The second decoder 113 may perform addressing on the column of the memory cell array 111 using a control address based on the second address bit.

Further, even when the address multiplexer 116 does not receive the second address bit (not illustrated), if the fuse bit is set to the second value, the memory 110 may operate in a similar manner.

For example, if the fuse bit is set to the second value and the memory 110 operates in the second mode, the second address buffer 115 may receive the second address bit from the outside. The address multiplexer 116 may latch the first address bit to the first address buffer 114. The address multiplexer 116 may not latch the second portion (Address bit 1b) of the first address bit to the second address buffer 115.

The second decoder 113 may perform addressing using the second address bit latched to the second address buffer 115.

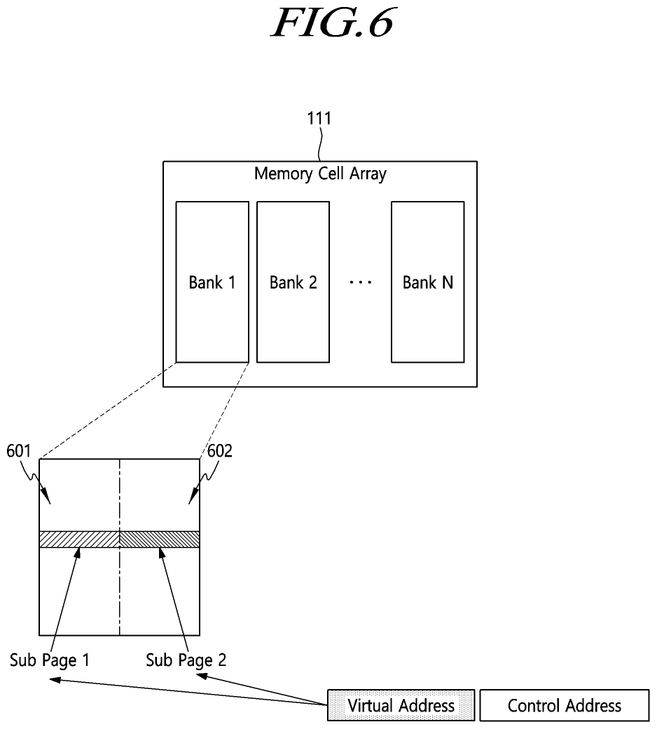

FIG. 6 is a view illustrating a method of performing addressing by a memory according to embodiments of the present disclosure.

Referring to FIG. 6, a memory cell array 111 may be divided into a plurality of banks. Each of the plurality of banks may include a plurality of word lines WL, a plurality of bit lines BL, and a plurality of memory cells. A write operation or a read operation may be performed in units of banks according to external control.

If the memory 110 receives the first address bit and the second address bit from the outside, the memory 110 may perform addressing on the row address using the first address bit, and may perform addressing on the column address using the second address bit.

When operating in the first mode according to the set value of the fuse bit, the memory 110 may perform addressing using a portion of the first address bit or the second address bit and another address bit together.

For example, the bank included in the memory cell array 111 may be divided into a first sub page such as a portion indicated by 601 and a second sub page such as a portion indicated by 602.

The memory 110 may select a row, which is the target for the operation, based on the first portion (Address bit 1a) of the first address bit.

The memory 110 may select a first sub page or a second sub page based on the second portion (Address bit 1b) of the first address bit. A virtual address based on the second portion (Address bit 1b) of the first address bit may indicate the first sub page or the second sub page.

The memory 110 may select the column, which is the target for the operation in the first sub page or the second sub page, based on the second address bit. A control address based on the second address bit may indicate the operation bit line among the bit lines BL included in the first sub page or the second sub page.

When the value of the fuse bit is set to the second value, the memory 110 may perform row addressing and column addressing using each of the first address bit and the second address bit.

Since a sub page may be selected using the second portion (Address bit 1b) of the first address bit, addressing of a column larger than the size of the second address bit may be possible.

Further, whether to use the second portion (Address bit 1b) of the first address bit may be determined according to the set value of the fuse bit, so that addressing by the same controller 120 may be performed even when the memory cell array 111 included in the memory 110 is different in design.

As the second portion (Address bit 1b) of the first address bit, at least a portion of the portion not used in the first address bit for row addressing may be used.

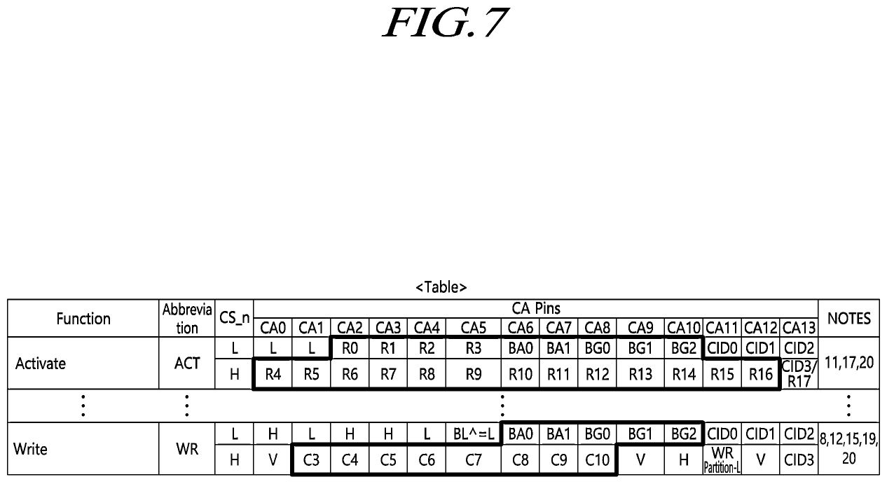

FIG. 7 is a view illustrating an example of an address bit received by a memory according to embodiments of the present disclosure.

FIG. 7 illustrates examples of a first address bit used for row addressing and a second address bit used for column addressing.

The first address bit may be transmitted according to, e.g., an

active command. The first address bit may be composed of at least a portion of R0 to R16. Some of R0 to R16 may be used for row addressing. In some embodiments of the present disclosure, the first address bit may include BA0, BA1, BG0, BG1, BG2, or the like. BA0 and BA1 may be used to address a bank. BG0, BG1, and BG2 may be used to address a bank group.

The second address bit may be transmitted according to, for example, a write command. As another example, the second address bit may be transmitted according to a read command. The second address bit may be composed of at least a portion of C3 to C10.

All of C3 to C10 available in the second address bit may be used for column addressing.

Only a portion of R0 to R16 available in the first address bit may be used for row addressing. Since only a portion of the first address bit is used for row addressing, at least a portion of the rest of the first address bit may be used for column addressing. A portion of R0 to R16 may correspond to the first portion (Address bit 1a) of the first address bit, and at least a portion of the rest may correspond to the second portion (Address bit 1b) of the first address bit. A portion of R0 to R16 may be used to indicate a subpage or a bit line group. C3 to C10 may be used to address a column included in a sub page or bit line group indicated by a portion of R0 to R16. A portion of R0 to R16 may be latched to the first address buffer 114. At least a portion of the rest of R0 to R16 that is not latched to the first address buffer 114 may be latched to the second address buffer 115. C3 to C10 may be latched to the second address buffer 115. Column addressing may be performed using a portion of the R0 to R16, and C3 to C10 latched to the second address buffer 115.

Since the portion that is not used for row addressing, in the portion that may be used as the first address bit, may be used for column addressing, the addressing method may be adjusted without changing or adding the address bit. Addressing of columns larger over an addressable range may be performed by the second address bit.

The first address bit and the second address bit may be transmitted in the same period or may be transmitted in different periods.

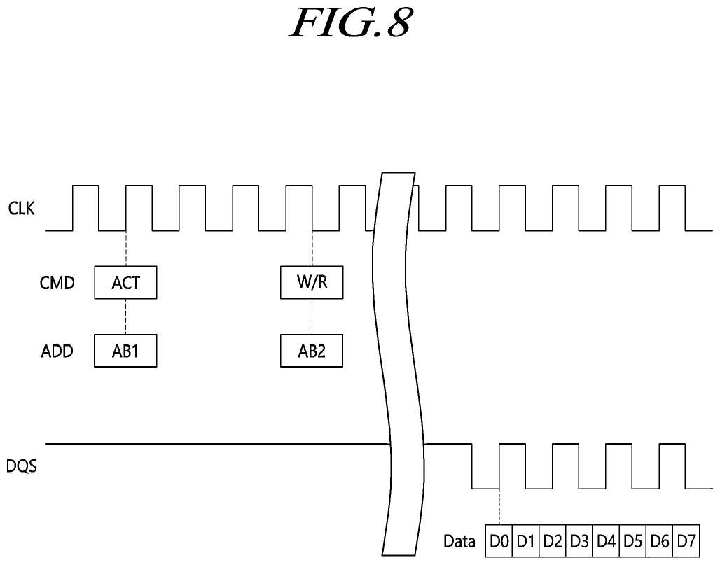

FIG. 8 is a view illustrating an example of timing at which a memory receives an address bit according to embodiments of the present disclosure.

Referring to FIG. 8, an example in which a command and an address are transmitted according to a clock signal CLK is shown. A data signal DQS may be transmitted after the command and the address are transmitted.

The memory 110 may receive a first address bit in a first period. The memory 110 may receive the first portion (Address bit 1a) and the second portion (Address bit 1b) of the first address bit in the first period.

The memory 110 may receive a second address bit in a second period. The second period may be different from the first period.

The first period may mean a period during which an active command ACT is transmitted. The first period may mean a period overlapping at least a portion of the period during which the active command is transmitted. The first portion (Address bit 1a) and the second portion (Address bit 1b) (together, AB1) of the first address bit may be transmitted during a period during which the active command is transmitted or at least a portion of the period during which the active command is transmitted.

The second period may mean a period during which a write command or a read command W/R is transmitted.

The second period may mean a period overlapping at least a portion of the period during which the write command or the read command is transmitted. The second address bit AB2 may be transmitted during the period during which the write command or the read command is transmitted, or a period overlapping at least a portion of the period.

The memory 110 may receive the second portion (Address bit 1b) of the first address bit and the second address bit in different periods. The memory 110 may latch the second portion (Address bit 1b) of the first address bit and the second address bit received in different periods to the address buffer. Based on the second portion (Address bit 1b) of the first address bit and the second address bit latched to the address buffer, addressing of a column having a size larger than that of the second address bit may be performed.

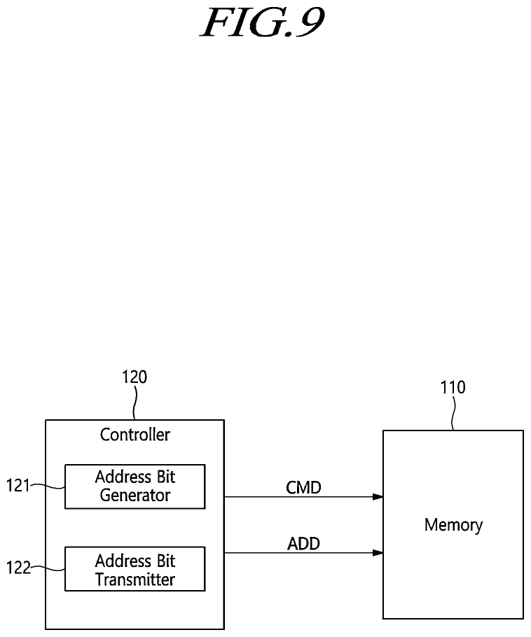

FIG. 9 is a view illustrating a configuration of a controller according to embodiments of the present disclosure.

Referring to FIG. 9, a controller 120 may include an address bit generator 121 and an address bit transmitter 122.

The address bit generator 121 may generate a first bit indicating an operation word line among a plurality of word lines WL included in the memory 110. The address bit generator 121 may generate a second bit indicating one of a plurality of sub pages included in the memory 110.

The first bit and the second bit may collectively be referred to as a first address bit. The first bit may correspond to the first portion (Address bit 1a) of the first address bit, and the second bit may correspond to the second portion (Address bit 1b) of the first address bit.

The address bit generator 121 may generate a third bit indicating the operation bit line among the plurality of bit lines BL included in the sub page indicated by the second bit.

The third bit may mean a second address bit.

The address bit transmitter 122 may transmit the first bit and the second bit to the memory 110 in the first period. The first period may be a period during which an active command is transmitted or a period overlapping at least a portion of the period during which an active command is transmitted.

The address bit transmitter 122 may transmit the third bit to the memory 110 in the second period. The second period may be a period during which a write command or a read command is transmitted, or a period overlapping at least a portion of the period during which a write command or a read command is transmitted.

The memory 110 may perform row addressing using the first bit received in the first period. The memory 110 may perform column addressing using the second bit received in the first period and the third bit received in the second period.

Since the controller 120 uses the rest of one of the first address bit and the second address bit when addressing an operation line by the other of the first address bit and the second address bit, the addressing range may be extended without changing the size of the address bit. For example, the rest of the first address bit may be used for addressing with the second address bit, or the rest of the second address bit may be used for addressing with the first address bit.

Addressing on the memory 110 having a different or extended addressing range may be performed using the same controller 120.

Since addressing on various types or extended memories 110 is possible without changing the controller 120, optimization or extension of the memory 110 may be facilitated.

Although various embodiments of the disclosed technology have been described with particular specifics and varying details for illustrative purposes, those skilled in the art will appreciate that various modifications, additions and substitutions may be made based on what is disclosed or illustrated in the present disclosure without departing from the spirit and scope of the present disclosure as defined in the following claims.

What is claimed is:

1. A storage device, comprising:
a memory including a memory cell array including a plurality of word lines and a plurality of bit lines, a first decoder selecting an operation word line from among the plurality of word lines, and a second decoder selecting an operation bit line from among the plurality of bit lines; and
a controller transmitting a first address bit and a second address bit, a first portion of the first address bit indicating the operation word line for selection, and a second portion of the first address bit and the second address bit indicating the operation bit line for selection.

2. The storage device of claim 1, wherein the memory further includes a column address buffer to which the second portion of the first address bit and the second address bit are latched.

3. The storage device of claim 2, wherein the memory further includes an address multiplexer latching the second portion of the first address bit to the column address buffer or the second decoder.

4. The storage device of claim 3, wherein the address multiplexer latches the first portion of the first address bit to a row address buffer or the first decoder.

5. The storage device of claim 4, wherein the memory has a fuse bit set to a first value in a first mode and set to a second value in a second mode and, if the fuse bit is set to the first value, latches the second portion of the first address bit to the column address buffer.

6. The storage device of claim 5, wherein the memory latches the second portion of the first address bit to the row address buffer if the fuse bit is set to the second value.

7. The storage device of claim 5, wherein the memory latches the first address bit, except for the second portion of the first address bit, to the row address buffer if the fuse bit is set to the second value.

8. The storage device of claim 5, wherein in the second mode, the second portion of the first address bit is not used.

9. The storage device of claim 1, wherein the plurality of bit lines are divided into two or more bit line groups, and wherein the second portion of the first address bit indicates one of the two or more bit line groups.

10. The storage device of claim 1, wherein the memory cell array is divided into two or more sub pages, and wherein the second portion of the first address bit indicates one of the two or more sub pages.

11. The storage device of claim 1, wherein the second portion of the first address bit is transmitted in a first period, and the second address bit is transmitted in a second period different from the first period.

12. The storage device of claim 1, wherein at least a portion of a period during which the second portion of the first address bit is transmitted overlaps a period during which an active command is transmitted, and at least a portion of a period during which the second address bit is transmitted overlaps a period during which a write command or a read command is transmitted.

13. A memory device, comprising:
a plurality of first driving lines arranged in a first direction;
a plurality of second driving lines arranged in a second direction crossing the first direction;
a first decoder selecting a first driving line operating from among the plurality of first driving lines based on a first portion of a first address bit; and
a second decoder selecting a second driving line operating from among the plurality of second driving lines based on a second portion of the first address bit and a second address bit.

14. The memory device of claim 13, further comprising an address buffer to which the second portion of the first address bit and the second address bit are latched.

15. The memory device of claim 14, further comprising an address multiplexer latching the second portion of the first address bit to the address buffer.

16. The memory device of claim 15, wherein the address multiplexer latches the first portion of the first address bit to an address buffer different from the address buffer to which the second portion of the first address bit is latched.

17. The memory device of claim 13, wherein the first portion and the second portion of the first address bit are received in a first period, and the second address bit is received in a second period different from the first period.

18. A controller, comprising:
an address bit generator generating a first bit indicating an operation word line among a plurality of word lines, a second bit indicating one among a plurality of sub pages, and a third bit indicating an operation bit line among a plurality of bit lines included in a sub page indicated by the second bit; and
an address bit transmitter transmitting the first bit and the second bit in a first period and transmitting the third bit in a second period.

19. The controller of claim 18, wherein the address bit transmitter transmits the first bit and the second bit in a period overlapping at least a portion of a period during which an active command is transmitted.

20. The controller of claim 18, wherein the address bit transmitter transmits the third bit in a period overlapping at least a portion of a period during which a write command or a read command is transmitted.
